(19) United States
(12) Patent Application Publication
(10) Pub. No.: US 2025/0023516 A1
(43) Pub. Date: Jan. 16, 2025

(54) CONTACT DEVICE AND ARRANGEMENT AND METHOD FOR CHARACTERIZING SUB-CELLS

(71) Applicant: MEYER BURGER (GERMANY) GMBH, Hohenstein-Ernstthal (DE)

(72) Inventors: Andreas WALTINGER, Hohenstein-Ernstthal (DE); Frank SCHITTHELM, Hohenstein-Ernstthal (DE)

(73) Assignee: MEYER BURGER (GERMANY) GMBH, Hohenstein-Ernstthal (DE)

(21) Appl. No.: 18/712,607

(22) PCT Filed: Nov. 18, 2022
(86) PCT No.: PCT/EP2022/082398

§ 371 Date: May 22, 2024

(30) Foreign Application Priority Data
Nov. 24, 2021 (EP) 21210237.0

(51) Int. Cl. H02S 50/15; H01L 31/05

(52) U.S. Cl. CPC H02S 50/15; H01L 31/0516

(57) ABSTRACT

The invention relates to a contact device for contacting multiple sub-cells of solar cells that are physically and electrically separate from one another and also to an arrangement and a method for characterising such sub-cells. The contact device comprises a planar carrier element with at least two back-side contact arrangements or at least two planar carrier elements each with at least one back-side contact arrangement, at least one front-side contact arrangement and at least one holding device for fixing the sub-cells on the planar carrier element or elements. Each back-side contact arrangement and each front-side contact arrangement corresponds to a back-side or front-side contact, respectively, of one of the sub-cells. Either the back-side contact arrangements of the individual sub-cells can be electrically contacted separately, while the front-side contact arrangements of all the sub-cells are electrically connected to a common front-contact arrangement and can be contacted with a common front-side potential, or the front-side contact arrangements of the individual sub-cells can be electrically contacted separately, while the back-side contact arrangements of all the sub-cells are electrically connected to a common back-contact arrangement and can be contacted with a common back-side potential. With the aid of the contact device, multiple sub-cells can be electrically characterised at the same time during a lighting operation or one after the other during successive lighting operations.

The object of the present invention is a contact device for contacting multiple sub-cells of solar cells that are physically and electrically separate from one another. The invention further discloses an arrangement for characterising sub-cells resulting from the division of one or more full cells, and a method for characterising sub-cells resulting from the division of full cells.

The invention relates to any type of solar cell in which electrical charge carriers are separated by exposure to light. These include solar cells with a pn junction or those in which the required band bending is caused by different materials (heterojunction).

The front side and back side of the solar cells are contacted in order to remove the charge carriers generated when exposed to sunlight. Ohmic conduction losses (Pₗₒₛₛ=I²·Rₛₑᵣ) occur as a result of the serial connection of the solar cells in the module. In order to reduce these losses, it was decided to divide complete solar cells, herein also referred to as full cells, into smaller sub-cells in order to also divide or reduce the conducted current I. The lateral dimensions of these sub-cells are smaller. The generated current I and the losses in the cables are therefore also reduced. Starting from a division of complete solar cells into two sub-cells (half-cells), further subdivisions (3, 4, 5, 6 . . . n sub-cells) are now also state of the art.

For various reasons, full cells with large lateral dimensions are initially produced during production. It has been found that, after qualification (electrical measurement), when dividing the full cells into sub-cells, the measurement data cannot be related to the half of the respective sub-cell for the purposes of the required measurement accuracy. However, losses due to division and other subsequent process steps, e.g. edge passivation and light soaking, cannot be recorded either. Therefore, an electrical characterisation of the sub-cells after their generation is necessary.

There are a number of devices that are meant to test the operating parameters of half-cells and other subdivisions of a full cell.

The subject of CN 207 117 571 U is a device which is to allow half-cells to be tested in testers intended for full cells. The device contacts a half-cell by means of a plurality of pins. For testing different cell sizes, it is intended that some of the pins can be lowered. A central pin group remains in a protruding state, while the height of other pin groups surrounding the central pin group can be reduced. In this way, the necessary pins for the current test task (full cell, half-cell, sub-cells) can always be brought into a working position and used. It is not intended to perform simultaneous measurements on multiple sub-cells.

CN 210 123 451 U and CN 212 379 533 U describe carriers for testing half-cells (optionally sub-cells) by surface contacting. The carriers have brackets with contact tips arranged thereon. The brackets are meant to be movable to adapt to different cell sizes. The parallel testing of multiple sub-cells is not mentioned.

WO2017116716A1 describes a solar cell arrangement in which a full cell is provided with a backside metallisation. The full cell is then subdivided into a plurality of sub-cells, with a common carrier remaining as the back-side electrode. This advantageously allows for contacting the back-side electrode at only one point. The disadvantage, however, is that a new separation step is necessary after the measurements to finally separate the sub-cells. This can result in further errors that remain unnoticed.

FR 3 097 705 A1 describes a method for electrically characterising full cells, sub-cells generated from full cells, and modules from the sub-cells. For measuring, the sub-cells are arranged on a carrier element (chuck) which has a separate back-side contact arrangement for each sub-cell, and each sub-cell is contacted with a front-side contact arrangement. The front-side and back-side contact arrangements assigned to an individual sub-cell are each contacted separately by a measuring device. To characterise a module consisting of sub-cells connected in parallel, all front-contact arrangements and all back-side contact arrangements are then electrically connected to each other.

In “Analysis of edge losses on silicon heterojunction half solar cells,” Solar Energy Materials & Solar Cells 204 (2020) 110213, Gerenton et al. also disclose a method for the electrical characterisation of sub-cells, which is used to assess the losses resulting from the division. In said method, either each sub-cell is measured individually, with the other sub-cells belonging to a full cell being replaced by dummy cells, or all front-contact arrangements or all back-side contact arrangements are electrically connected to each other.

The existing system technology is designed for testing full cells and is therefore suitable only to a limited extent for use with sub-cells. In particular, it is not possible to characterise multiple sub-cells at the same time.

The object is therefore to propose a device that can be used to qualify sub-cells resulting from full cells in known systems for full cells. Furthermore, an arrangement and a method for qualifying sub-cells by means of the contact device according to the invention are to be provided.

Qualification (testing) is carried out by exposing the solar cell or the sub-cells to a flash of light, usually over a period of 4 ms to 600 ms. During this time, a current-voltage characteristic measurement (I-V measurement) is carried out to record the characteristic. Qualification allows the sub-cells to be classified into corresponding quality levels.

For qualification, the solar cells or sub-cells are arranged on a planar carrier element and irradiated with the flash of light on the side facing away from the carrier element. The side illuminated by the flash of light is the illumination side. It is identical to the side on which the solar cells will later receive sunlight.

According to the invention, the object is achieved with a contact device according to claim 1. An arrangement for characterising sub-cells resulting from the division of a full cell is disclosed in an independent claim. A method for characterising sub-cells resulting from the division of full cells is the subject of a further independent claim. Advantageous embodiments or methods are disclosed in the related sub-claims.

The contact device according to the invention for contacting multiple sub-cells that are physically and electrically separate from one another, each of the sub-cells having at least one back-side contact and at least one front-side contact, comprises:
a planar carrier element with at least two back-side contact arrangements, or at least two planar carrier elements each with at least one back-side contact arrangement, wherein each back-side contact arrangement corresponds to the at least one back-side contact of one of the sub-cells and is suitable for electrically contacting the at least one back-side contact of the sub-cell;
at least one front-side contact arrangement, wherein each front-side contact arrangement corresponds to the at least one front-side contact of one of the sub-cells and is suitable for electrically contacting the at least one front-side contact of the sub-cell; and
at least one holding device for fixing the sub-cells on the planar carrier element or elements,
wherein
a) the back-side contact arrangements of the individual sub-cells can be electrically contacted separately, while the front-side contact arrangements of all the sub-cells are electrically connected to a common front-contact arrangement and can be contacted with a common front-side potential,
or
b) the front-side contact arrangements of the individual sub-cells can be electrically contacted separately, while the back-side contact arrangements of all the sub-cells are electrically connected to a common back-contact arrangement and can be contacted with a common back-side potential.

In the present context, “front-side contact” means that there is an electrically conductive contact to the first region of the absorber layer, and “back-side contact” means that there is an electrically conductive contact to the second region of the absorber layer. This means that the front-side and back-side contacts can be arranged on opposite sides or on the same physical side (usually the back side) of the solar cell. Cell types in which the front-side and back-side contacts are on the same physical side are, in particular, IBC cells (interdigited back contact cells), in which the front-side and back-side contacts on the back side of the cells contact the different conductor carrier type regions.

The sub-cells, which are tested simultaneously with the contact device according to the invention, can have resulted from the division of one and the same full cell or also of different full cells.

The planar carrier elements are preferably designed as printed circuit boards (PCBs). In this context, “planar” means that the carrier elements are designed in the manner of a PCB with raised contacts and/or conductor tracks. Preferably, one or more planar carrier elements are arranged, preferably screwed, on a chuck for solar cells. Advantageously, this releasable connection allows for changing the planar carrier elements as required.

In a first embodiment, a planar carrier element with at least two back-side contact arrangements is provided. The back-side contactings are located on the planar carrier element and correspond to the back-side contacts of the sub-cells.

In the present context, “correspond” means that the back-side contacts of the sub-cells establish an electrically conductive connection (by contact) to the back-side contact arrangement of the planar carrier element once the sub-cells have been applied to the respective planar carrier element. For this purpose, the back-side contact arrangement of the planar carrier element has corresponding contact points and/or conductor tracks.

In a second embodiment, at least two planar carrier elements each with at least one back-side contact arrangement are provided. Each back-side contact arrangement corresponds to at least one back-side contact of one of the sub-cells and makes electrical contact with the at least one back-side contact of the sub-cell.

Furthermore, in both embodiments there are preferably electrical connection options for the electrical supply lines of the at least one measuring device provided on the edge of the planar carrier element.

The holding device fixes the sub-cell or sub-cells to the respective planar carrier devices from the illumination side. The holding devices can, for example, be designed as a grid that can be fixed in a holding position in which it presses the sub-cells against the planar carrier element (e.g. the PCB). Other holding devices have one or more brackets, one or more spring elements, or some other releasable clamping device. Other possible solutions provide for one or more suction devices.

In a preferred embodiment, the holding device is a grid or an arrangement of parallel thin wires.

In embodiments, the at least one front-side contact arrangement is arranged on the illumination side of the sub-cells independently of the at least one holding device. Optionally, the front-side contact arrangement can be fixed in position together with the sub-cells by the holding device.

Optionally, the at least one front-side contact arrangement is also located on the carrier element or elements, but is designed to be electrically insulated from the back-side contact arrangements. This arrangement variant is preferred for IBC cells.

Furthermore optionally, the holding device, preferably the grid, also functions as a front-side contact arrangement for contacting the front-side contacts of the sub-cells.

For measuring, it is provided for either the back-side contacts of all sub-cells on the at least one planar carrier device to be connected to a common potential, or for all front-side contacts of the sub-cells to be connected to a common potential.

Further relevant data of the solar cells can be determined with the contact device according to the invention. This includes, for example:
local temperature increases measured with a thermal camera (bolometer) simultaneously with the determination of reverse currents
electroluminescence images of the sub-cells.

In that case, the associated sensors are integrated into the contact device, e.g. into the holding device or the carrier element or one of the contact arrangements.

The arrangement according to the invention for characterising (testing, qualifying) sub-cells resulting from the division of full cells has a lighting device for characterising full cells, and a chuck for holding full cells, on which one or more contact devices are arranged, as well as at least one measuring device. The one or more contact devices are suitable for contacting multiple sub-cells. The one or more measuring devices are configured to record measured values while the multiple sub-cells are being exposed to light by means of the lighting device.

According to the invention, the one or more measuring devices are configured to perform a simultaneous measurement between
the back-side contact arrangements of the individual sub-cells and the common front-contact arrangement, or
the front-side contact arrangement of the individual sub-cells and the common back-contact arrangement
during a lighting operation, or successive measurements on each sub-cell between
the back-side contact arrangements of one of the sub-cells and the common front-contact arrangement, or
the front-side contact arrangement of one of the sub-cells and the common back-contact arrangement
during successive lighting operations.

The basic structure of the characterisation arrangement according to the invention corresponds to the structure of arrangements for characterising full cells known from the prior art. The use of the contact device according to the invention in a system for characterising full cells makes extensive new purchases or reconstructions unnecessary.

Since the contact device according to the invention allows for qualifying multiple sub-cells, only the number or structure of the measuring devices must be adapted such as to allow for a parallel (simultaneous) or serial detection of the I-V curves of the sub-cells.

Parallel detection is achieved by assigning a measuring device known per se to each sub-cell to be qualified.

The arrangement according to the invention can advantageously be used for the simultaneous characterisation of multiple sub-cells by means of a lighting device for full cells from the prior art.

The method according to the invention for characterising sub-cells resulting from the division of full cells has at least the following steps in a first procedure:
providing an arrangement according to the invention for characterising (testing, qualifying) sub-cells resulting from the division of full cells;
arranging at least two sub-cells on the contact device and fixing the sub-cells by means of the at least one holding device;
electrically contacting one or more measuring devices with the back-side contact arrangements and the front-side contact arrangements; and
simultaneously illuminating all sub-cells and, at the same time, simultaneously recording the measured values of all the sub-cells located on the contact device.

Serial detection can be realised by providing a measuring device known per se with a circuit that successively connects the one measuring device to the sub-cells to be measured, i.e. to the contact arrangements of the at least one contact device assigned to them, and characterises one sub-cell at a time in the course of multiple lighting operations.

Thus, the method for characterising sub-cells resulting from the division of full cells has at least the following steps in a second procedure:
a) providing an arrangement according to the invention for characterising (testing, qualifying) sub-cells resulting from the division of full cells;
b) arranging at least two sub-cells on the contact device and fixing the sub-cells by means of the at least one holding device;
c) electrically contacting the measuring devices with the back-side contact arrangements and the front-side contact arrangements of a first sub-cell; and
d) simultaneously illuminating all sub-cells and, at the same time, recording the measured values of the first sub-cell,
e) electrically contacting the measuring devices with the back-side contact arrangements and the front-side contact arrangements of a further sub-cell; and
f) simultaneously illuminating all sub-cells and, at the same time, recording the measured values of the further sub-cell;
g) repeating steps e) and f) until all sub-cells have been measured.

The electrical characteristics (I-V curves) of the individual sub-cells are determined from the measured values recorded. This is preferably done in one or more data processing devices contained in the measuring devices or to which the data from the measuring devices is transmitted.

The invention is not limited to the illustrated and described embodiments but also includes all embodiments which act identically within the meaning of the invention. Furthermore, the invention is also not limited to the especially described feature combinations but can also be defined by any other combination of particular features of all individual features disclosed overall, provided that the individual features are not mutually exclusive, or a specific combination of individual features is not explicitly excluded.

### FIGURES

FIG. 1 schematically shows the division of a full cell 1 into a first half-cell 1a and a second half-cell 1b.

FIG. 2 schematically shows a first embodiment of a contact device 2 on which the first and second half-cells 1a, 1b can be arranged. The contact device 2 has a planar carrier element 23 on which two back-side contact arrangements 21a, 21b that are electrically separate from one another are applied as conductor tracks. The back-side contact arrangements 21a, 21b that are electrically separate from one another are electrically contacted at connection points 22a, 22b. The contact device 2 further has a holding device which at the same time functions as a common front-side contact arrangement 3 and which in the embodiment shown is attached to the carrier element 23. The front-side contact arrangement 3 is designed as a grid 31. It is electrically contacted via a connection point 32. FIG. 2 further shows a chuck 4, which holds the contact device 2, on which the two half-cells 1a, 1b are arranged.

FIG. 3 shows a schematic top view of how the two half-cells 1a, 1b are arranged on the contact device 2 according to FIG. 2. The holding device/front-side contact arrangement 3 is not yet closed.

FIG. 4 schematically shows the top view according to FIG. 3 with closed holding device (grid)/front-side contact arrangement 3.

FIG. 5 schematically shows the measuring arrangement for the first embodiment of the contact device 2 with separate back-side contact arrangements for each half-cell 1a, 1b, and with a common front-side contact arrangement 3. The first measuring device 5a contacts the first back-side contact arrangement (not shown) at connection point 22a by means of the electrical supply line 51a and the common connection point 32 of the front-side contact arrangement 3 by means of the electrical supply line 52a. The second measuring device 5b contacts the second back-side contact arrangement (not shown) at connection point 22b by means of the electrical supply line 51b and the common connection point 32 of the front-side contact arrangement 3 by means of the electrical supply line 52b.

FIG. 6 shows a schematic top view of a second embodiment of a contact device 2 on which the first and second half-cells 1a, 1b are arranged, wherein the contact device 2 here has a common back-side contact arrangement (not shown) and two front-side contact arrangements 3a, 3b that are electrically separate from one another. The common back-side contact arrangement is electrically contacted via the connection point 22. Each of the two front-side contact arrangements 3a, 3b is designed as a grid 31a, 31b. The two grids 31a, 31b further act as a holding device for the two half-cells 1a, 1b. The contact device 2 is arranged on the chuck 4.

FIG. 7 schematically shows the top view according to FIG. 6 with closed holding devices (grids)/front-side contact arrangements 3a, 3b.

FIG. 8 schematically shows the measuring arrangement for the second embodiment of the contact device 2 with separate grids 31a, 31b as front-side contact arrangements 3a, 3b for each half-cell 1a, 1b, and with a common back-side contact arrangement (not shown). The first measuring device 5a contacts the first front-side contact arrangement 3a at connection point 32a by means of the electrical supply line 52a and the common connection point 22 of the back-side contact arrangement by means of the electrical supply line 51a. The second measuring device 5b contacts the second front-side contact arrangement 3b at connection point 32b by means of the electrical supply line 52b and the common connection point 22 of the back-side contact arrangement by means of the electrical supply line 51b.

FIG. 9 schematically shows the arrangement of the contact device 2, carried by the chuck 4, in a conventional device 6 for the qualification of full cells (test device). The contact device 2 has separate back-side contact arrangements and a common front-side contact arrangement 3 (analogous to the first embodiment of the contact device in FIG. 2). The parallel measurements on the two half-cells 1a, 1b are shown schematically. The measurements are taken when a lighting device 61 having, for example, halogen lamps emits a flash of light 62 simultaneously onto both half-cells 1a, 1b.

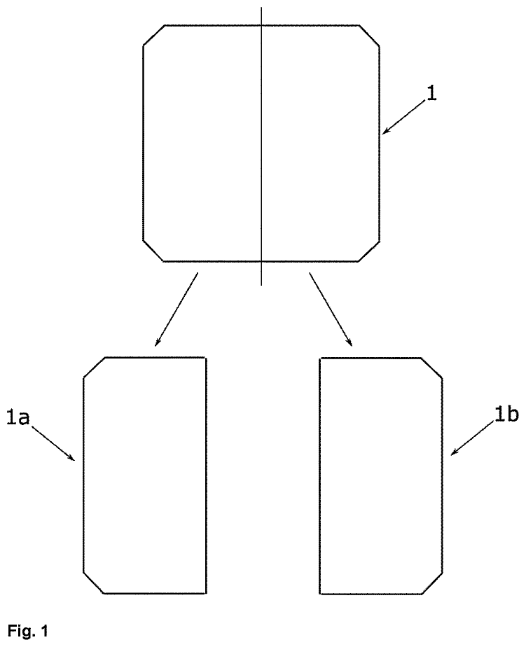

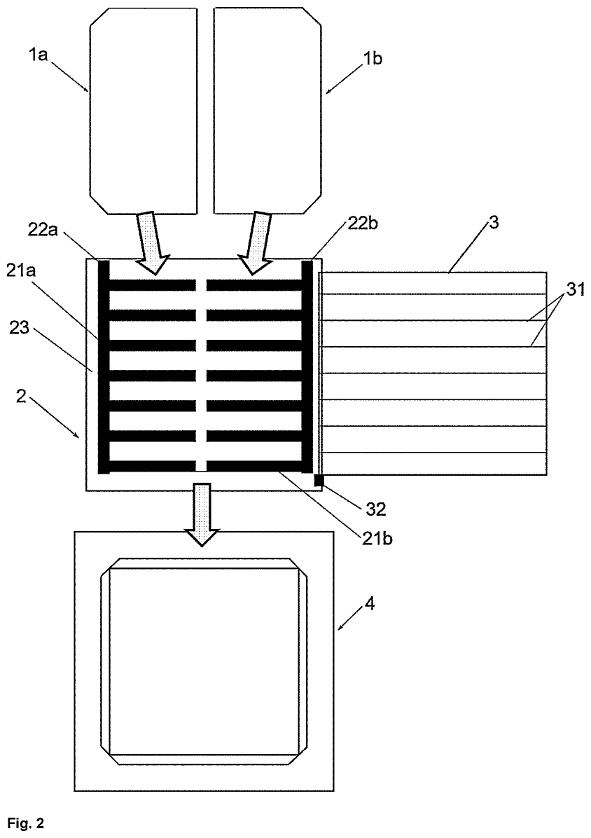

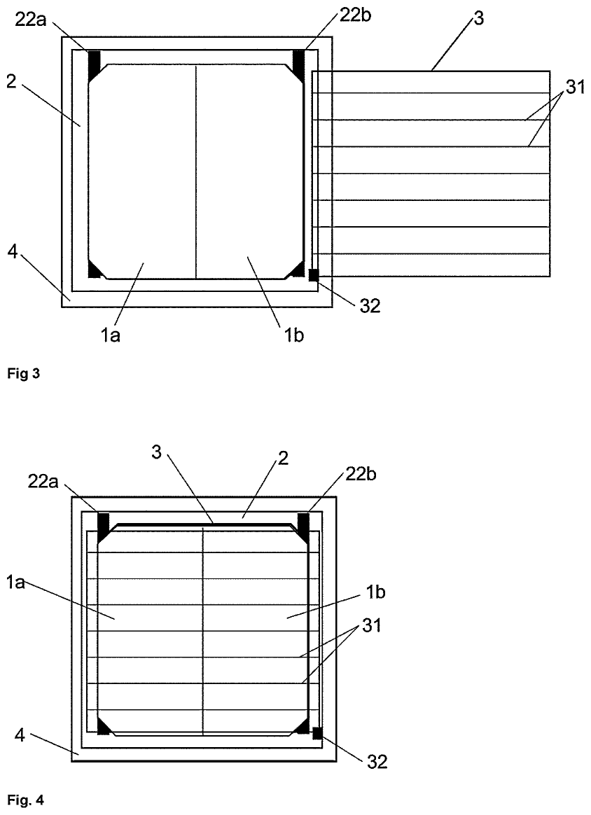

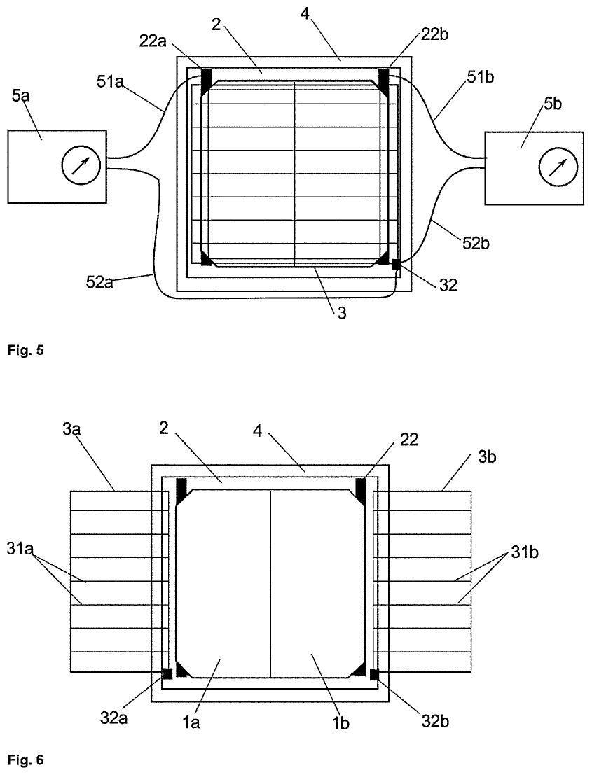

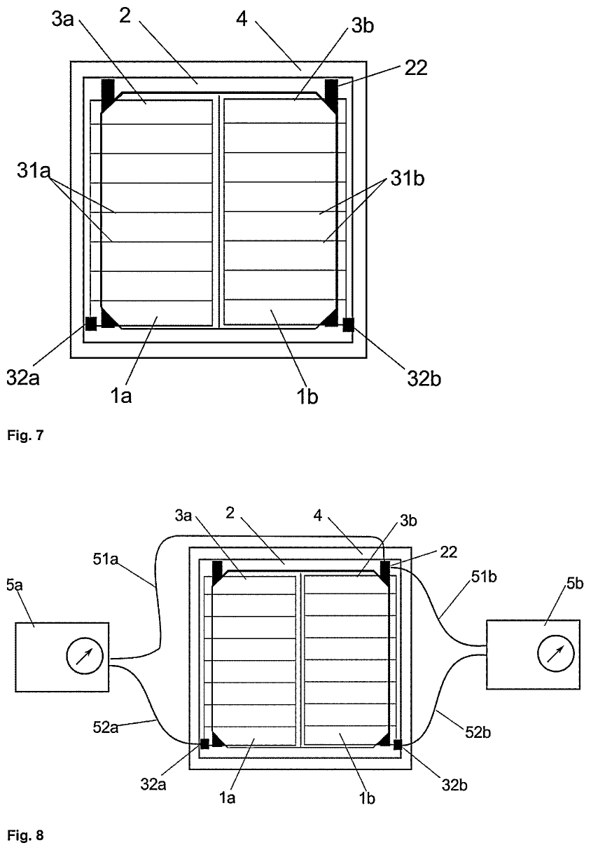

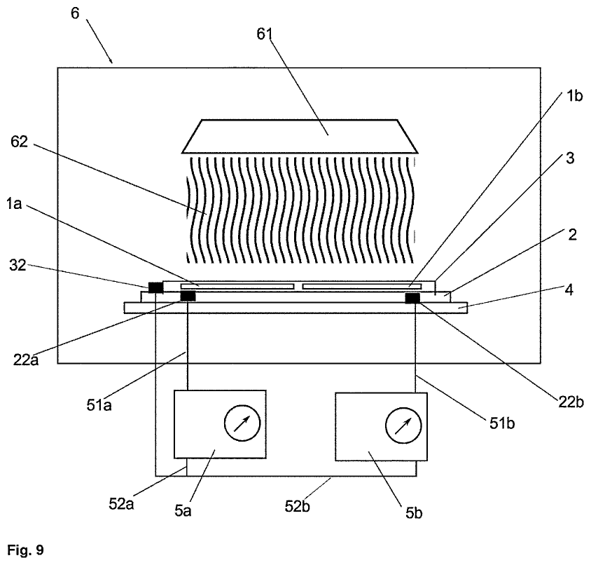

### Exemplary Embodiment

An exemplary contact device 2 according to the invention has a planar carrier element 23 designed as a PCB. The dimensions of the PCB are 170 mm×170 mm. Two back-side contact arrangements 21a, 21b that are electrically separate from one another are applied to the PCB, with the contacts of one back-side contact arrangement 21a, 21b corresponding to the back-side contacts of one half-cell 1a, 1b in each case. Each back-side contact arrangement 21a, 21b also has conductor tracks leading to connection points 22a, 22b for the measuring devices on the side of the planar carrier element 23. The half-cells 1a, 1b can thus be connected electrically separate from one another to a single or common measuring device, and a back-side potential can be applied to them separately from one another. The planar carrier element 23 is screwed onto a chuck 4 of the CELL CONTACTING UNIT type made by Pasan S. A. for full cells.

Furthermore, the planar carrier element 23 carries a hinged grid 31 which, in addition to holding the half-cells 1a, 1b in position, also realises front-side contacting of both half-cells 1a, 1b. The grid 31 is made of a conductive material. A connection point 32 for the measuring devices is provided at the pivot point of the grid 31 on the planar carrier element 23. The common front-side potential for all sub-cells arranged on the planar carrier element 23 is applied at said connection point.

For measuring, two half-cells 1a, 1b resulting from the central division of full cells are placed on the contact device 2. The half-cells 1a, 1b are fixed to the planar carrier element by the grid 31. The front-side contacts are contacted together by the grid 31, and the back-side contacts of the two half-cells 1a, 1b are contacted separately by the back-side contact arrangements 21a, 21b. The grid 31 thus also functions as a front-side contact arrangement 3. Two measuring devices 5a, 5b belonging to the SpotLIGHT XLP/XLS150 type test device are electrically connected to the half-cells 1a, 1b via the connection point 32 of the front-side contact arrangement 3.

The chuck 4 with the contact device 2 and the half-cells 1a, 1b is placed in the conventional SpotLIGHT XLP/XLS150 type test device 6. The electrical characteristics of the half-cells 1a, 1b are then recorded during the lighting operations (flashes of light 62). The flashes of light 62 are generated by means of a combined xenon/LED lamp lighting of the lighting device 61 for a period of 5 ms xenon light and up to 600 ms LED light. Current-voltage characteristics are generated as part of the recording of the electrical characteristics.

The current/voltage characteristics are recorded over up to 3 quadrants as current/voltage measurement pairs (light characteristic->illuminated in the flow direction of the diode, dark characteristic->not illuminated in the flow direction, inverse dark characteristic->not illuminated in the reverse direction)

The electrical characteristics of the two half-cells 1a, 1b are determined from the measured values. They include:

| | Short | |
|---|---|---|
| Value | identifier | Description |
| Short-circuit | Isc | Maximum current under lighting |
| current | | |
| Open circuit | Voc | Maximum voltage under lighting |
| voltage | | |
| Fill factor | FF | Ratio of maximum power of the cell |
| | | to theoretically achievable |
| | | maximum power of the cell: |
| | | Pmpp/(Isc*Voc) |
| Maximum power of | Pmpp | Maximum power of the cell: V*I (V) |
| the cell | | |
| Voltage at | Vmpp | |
| maximum cell | | |
| power | | |
| Current at | Impp | |
| maximum cell | | |
| power | | |
| Efficiency of the | ETA | Power of the cell in relation to the |
| cell | | irradiated light output |
| Series resistance | Rser | Calculated internal series |
| | | resistance of the solar cell from the |
| | | simplified solar cell equivalent |
| | | circuit diagram |
| Parallel resistance | Rsh | Calculated internal parallel |
| (shunt resistance) | | resistance of the solar cell from the |
| | | simplified solar cell equivalent |
| | | circuit diagram |
| Reverse current of | Irev | Reverse current at different |
| the solar cell during | | reverse voltages actively applied to |
| inverse operation | | the cell. |

Based on the electrical characteristics determined, the half-cells 1a, 1b can then be classified into different quality levels. In particular, sub-cells with similar characteristics can be combined in common solar modules.

### LIST OF REFERENCE SIGNS

1 Full-cell
1a First half-cell
1b Second half-cell
2 Contact device
21a First back-side contact arrangement
21b Second back-side contact arrangement
22 Connection point of a back-side contact arrangement
22a Connection point of the first back-side contact arrangement
22b Connection point of the second back-side contact arrangement
23 Planar carrier element (PCB)
3 Front-side contact arrangement
31 Grid of the front-side contact arrangement
31a First grid of the front-side contact arrangement
31b Second grid of the front-side contact arrangement
32 Connection point of the front-side contact arrangement
32a Connection point of the first front-side contact arrangement
32b Connection point of the second front-side contact arrangement
4 Chuck
5a First measuring device
5b Second measuring device
51a First electrical supply line from a back-side contact to the first measuring device
51b First electrical supply line from a back-side contact to the second measuring device
52a Second electrical supply line from a front-side contact to the first measuring device
52b Second electrical supply line from a front-side contact to the second measuring device
6 Conventional test device for full cells
61 Lighting device
62 Flash of light

1. A contact device for contacting multiple sub-cells (1a, 1b) that have resulted from the division of full cells (1) and that are physically and electrically separate from one another, each of the sub-cells (1a, 1b) having at least one back-side contact and at least one front-side contact,
wherein the contact device comprises:
a planar carrier element (23) with at least two back-side contact arrangements (21a, 21b), or at least two planar carrier elements (23) each with at least one back-side contact arrangement (21a, 21b), wherein each back-side contact arrangement (21a, 21b) corresponds to the at least one back-side contact of one of the sub-cells (1a, 1b) and is suitable for electrically contacting the at least one back-side contact of the sub-cell (1a, 1b);
at least one front-side contact arrangement (3), wherein each front-side contact arrangement (3) corresponds to the at least one front-side contact of one of the sub-cells (1a, 1b) and is suitable for electrically contacting the at least one front-side contact of the sub-cell (1a, 1b); and
at least one holding device for fixing the sub-cells (1a, 1b) on the planar carrier element or elements (23),
wherein:
a) the back-side contact arrangements (21a, 21b) of the individual sub-cells (1a, 1b) can be electrically contacted separately, while the front-side contact arrangements (3) of all the sub-cells (1a, 1b) are electrically connected to a common front-contact arrangement (3) and can be contacted with a common front-side potential,
or
b) the front-side contact arrangements (3) of the individual sub-cells (1a, 1b) can be electrically contacted separately, while the back-side contact arrangements (21a, 21b) of all the sub-cells are electrically connected to a common back-contact arrangement and can be contacted with a common back-side potential.

2. The contact device according to claim 1, wherein the at least one front-side contact arrangement (3) is also designed on the carrier element or elements (23), but is electrically insulated from the back-side contact arrangements (21a, 21b).

3. The contact device according to claim 1, wherein the at least one front-side contact arrangement (3) is arranged on the illumination side of the sub-cells (1a, 1b) independently of the at least one holding device.

4. The contact device according to claim 1, wherein the at least one front-side contact arrangement (3) is integrated into the holding device.

5. The contact device according to claim 1, wherein the at least one holding device comprises a grid (31), one or more brackets, one or more spring elements, or some other releasable clamping device.

6. The contact device according to claim 1, wherein the at least one holding device comprises a suction device.

7. The contact device according to claim 1, wherein the carrier element or elements (23) are designed as a printed circuit board (PCB).

8. An arrangement for characterising sub-cells (1a, 1b) resulting from the division of full cells (1), having a lighting device (61) for characterising solar cells, a chuck for holding solar cells, on which a contact device (2) according to claim 1 is arranged which is suitable for contacting multiple sub-cells (1a, 1b), and one or more measuring devices (5a, 5b) suitable for recording measured values while the multiple sub-cells (1a, 1b) are being exposed to light by means of the lighting device (61), wherein
a measuring device (5a, 5b) is assigned to each sub-cell (1a, 1b), and the multiple measuring devices (5a, 5b) are configured to perform a simultaneous measurement between
the back-side contact arrangements (21a, 21b) of the individual sub-cells (1a, 1b) and the common front-contact arrangement (3), or
the front-side contact arrangement (3) of the individual sub-cells (1a, 1b) and the common back-contact arrangement (21a, 21b) during the lighting operation,
or the one measuring device (5a, 5b) performs successive measurements on each sub-cell (1a, 1b) between
the back-side contact arrangements (21a, 21b) of one of the sub-cells (1a, 1b) and the common front-contact arrangement (3), or
the front-side contact arrangement (3) of one of the sub-cells (1a, 1b) and the common back-contact arrangement (21a, 21b) during successive lighting operations, wherein a circuit connects the one measuring device (5a, 6b) to another sub-cell (1a, 1b) after each lighting operation until all sub-cells (1a, 1b) have been characterised.

9. A method for characterising sub-cells (1a, 1b) resulting from the division of full cells (1), comprising at least the following steps:
providing an arrangement according to claim 8,
arranging at least two sub-cells (1a, 1b) on the contact device (2) and fixing the sub-cells (1a, 1b) by means of the at least one holding device;
electrically contacting the measuring devices (5a, 5b) with the back-side contact arrangements (21a, 21b) and the front-side contact arrangements (3); and
simultaneously illuminating all sub-cells (1a, 1b) and, at the same time, simultaneously recording the measured values of all the sub-cells (1a, 1b) located on the contact device (2).

10. A method for characterising sub-cells (1a, 1b) resulting from the division of full cells (1), comprising at least the following steps:
a) providing an arrangement according to claim 8,
b) arranging at least two sub-cells (1a, 1b) on the contact device (2) and fixing the sub-cells (1a, 1b) by means of the at least one holding device;
c) electrically contacting the measuring devices (5a, 5b) with the back-side contact arrangements (21a, 21b) and the front-side contact arrangements (3) of a first sub-cell (1a); and
d) simultaneously illuminating all sub-cells (1a, 1b) and, at the same time, recording the measured values of the first sub-cell (1a);
e) electrically contacting the measuring devices (5a, 5b) with the back-side contact arrangements (21a, 21b) and the front-side contact arrangements (3) of a further sub-cell (1b); and
f) Simultaneous illumination of all the sub-cells (1a, 1b) and parallel recording of the measured values of the other sub-cell (1b),
g) repeating steps e) and f) until all sub-cells (1a, 1b) have been measured.

11. The method according to claim 9, wherein the electrical characteristics (I-V curves) of the individual sub-cells (1a, 1b) are determined from the measured values.

12. A method simultaneous or serial characterisation of multiple sub-cells (1a, 1b) comprising providing the contact device according to claim 1 and illuminating the sub-cells with a lighting device (61) for full cells (1).

13. The contact device according to claim 5, wherein:
the at least one front-side contact arrangement (3) is also designed on the carrier element or elements (23), but is electrically insulated from the back-side contact arrangements (21a, 21b); or
the at least one front-side contact arrangement (3) is arranged on the illumination side of the sub-cells (1a, 1b) independently of the at least one holding device; or
the at least one front-side contact arrangement (3) is integrated into the holding device.

14. The contact device according to claim 6, wherein:
the at least one front-side contact arrangement (3) is also designed on the carrier element or elements (23), but is electrically insulated from the back-side contact arrangements (21a, 21b); or
the at least one front-side contact arrangement (3) is arranged on the illumination side of the sub-cells (1a, 1b) independently of the at least one holding device.

15. The contact device according to claim 14, wherein the at least one holding device comprises a grid (31), one or more brackets, one or more spring elements, or some other releasable clamping device.

16. The contact device according claim 2, wherein the carrier element or elements (23) are designed as a printed circuit board (PCB).

17. The contact device according claim 3, wherein the carrier element or elements (23) are designed as a printed circuit board (PCB).

18. The contact device according claim 4, wherein the carrier element or elements (23) are designed as a printed circuit board (PCB).

19. The contact device according claim 15, wherein the carrier element or elements (23) are designed as a printed circuit board (PCB).

20. The method according to claim 10, wherein the electrical characteristics (I-V curves) of the individual sub-cells (1a, 1b) are determined from the measured values.
